(19) United States
(12) Patent Application Publication
(10) Pub. No.: US 2026/0213141 A1
(43) Pub. Date: Jul. 23, 2026

(54) METHOD OF CLEANING SENSOR USED IN SEMICONDUCTOR MANUFACTURING TOOL

(71) Applicant: TAIWAN SEMICONDUCTOR MANUFACTURING COMPANY LTD., HSINCHU (TW)

(72) Inventors: YEN-HAO LIU, HSINCHU (TW); YEN-SHUO SU, HSINCHU CITY (TW); CHUEH-CHI KUO, KAOHSIUNG CITY (TW); WEI-HUAI CHIU, MIAOLI COUNTY (TW); LI-JUI CHEN, HSINCHU CITY (TW)

(21) Appl. No.: 19/032,137

(22) Filed: Jan. 20, 2025

(51) Int. Cl. H01J 37/32; H10P 76/20

(52) U.S. Cl. CPC H01J 37/32862; H01J 37/32357; H01J 37/32568; H01J 37/32935; H01J 2237/335; H10P 76/2041

(57) ABSTRACT

A sensor cleaning method is provided. The method includes processing a semiconductor wafer in a chamber. The method further includes using a first sensor to detect a parameter in the chamber during the processing of the semiconductor wafer. The method also includes generating cleaning plasma by a probe positioned in the chamber, wherein a gas is supplied to a passage in the probe and is excited into cleaning plasma by electric power supplied by electrodes positioned next to the passage. In addition, the method includes discharging the cleaning plasma from the probe toward the first sensor to remove contaminations formed on the first sensor.

### BACKGROUND

The manufacturing of integrated circuits (ICs) on silicon wafer substrates encompasses a series of intricate and precise steps to achieve the desired electronic functionalities. Typically, the process begins with the deposition of thin dielectric or conductive films onto the wafer surface. This deposition can be achieved through various methods, including thermal oxidation or a variety of chemical vapor deposition (CVD) techniques. Following film deposition, a circuit pattern is formed on a layer of photoresist material using photolithography. This pattern is then transferred to the underlying conductive layer through an etching process, which selectively removes material to create the intricate circuit pathways. After etching, the photoresist mask layer is stripped from the wafer, leaving behind the defined circuit structures. Each of these steps, including the photoresist stripping phase, presents ample opportunities for the accumulation of contaminants.

In processing tools performing the process above, numerous sensors are employed to monitor and control the internal environmental parameters to the manufacturing process. These sensors can include optical sensors, temperature sensors, pressure sensors, and others, each serving to provide real-time data that ensures process stability and consistency. In the semiconductor manufacturing environment outgassed by-products and other contaminants are generated that can adversely affect sensor performance. Outgassing refers to the release of volatile substances from materials within the tool, which can deposit onto sensor surfaces. This deposition adversely effects sensor’s ability to accurately detect and measure environmental parameters. As a result, the reliability and precision of the sensor data are compromised, potentially leading to process variations, reduced yield, and increased defect rates in the manufactured ICs.

Therefore, there is a need for an efficient and effective sensor cleaning method in order to maintain the integrity and performance of sensors and uphold the accuracy of real-time dynamic data measurements within semiconductor processing tools.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 is a flowchart of a method for manufacturing a semiconductor wafer, in accordance with certain embodiments of the present disclosure.

FIG. 2 is a schematic view of a processing system for performing the method illustrated in FIG. 1, in accordance with certain embodiments of the present disclosure.

FIGS. 3A and 3B are schematic views showing the mechanism for removing contamination from a sensor, in accordance with certain embodiments of the present disclosure.

FIG. 4 is a flowchart of an alternative method for manufacturing a semiconductor wafer, in accordance with other embodiments of the present disclosure.

FIG. 5 is a schematic view of a processing system while a probe being positioned in an idle position, in accordance with certain embodiments of the present disclosure.

FIG. 6 is a schematic view of a processing system while a probe being positioned in a first cleaning position, in accordance with certain embodiments of the present disclosure.

FIGS. 7A-7C are schematic views showing different stages of a sensor cleaning process, in accordance with certain embodiments of the present disclosure.

FIG. 8 is a schematic view illustrating one stage of the sensor cleaning process, in accordance with certain embodiments of the present disclosure.

FIG. 9 is a schematic view illustrating another stage of the sensor cleaning process, in accordance with certain embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as "first," "second" and "third" describe various elements, components, regions, layers and/or sections, these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation.

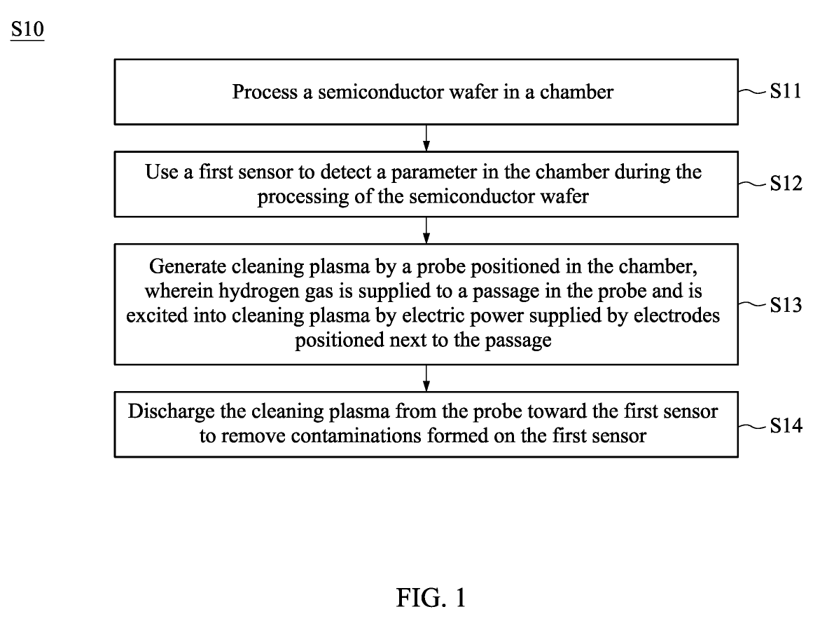

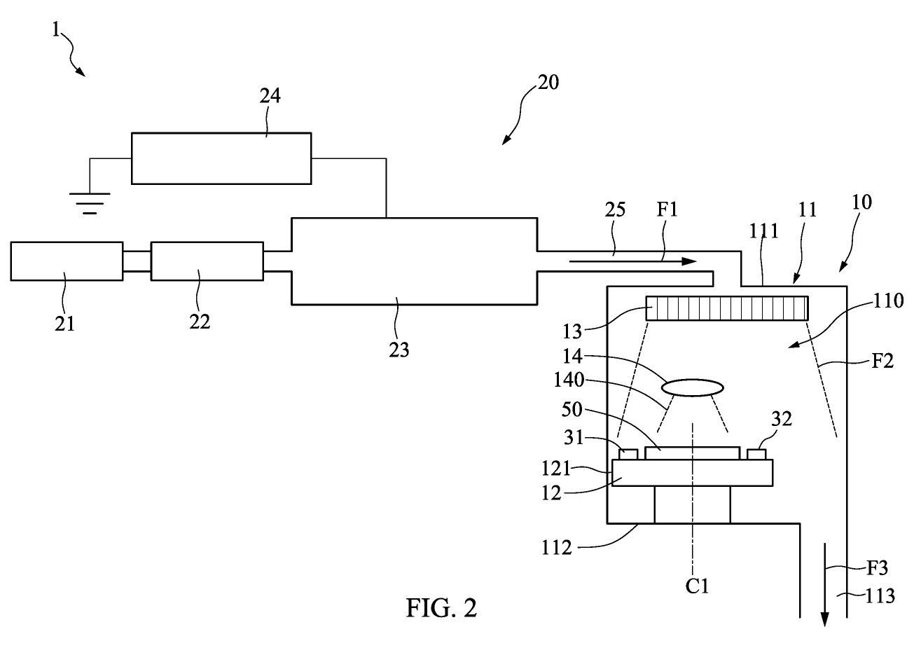

FIG. 1 is a flowchart of a method S10 for manufacturing a semiconductor wafer, in accordance with certain embodiments of the present disclosure. For illustration, the flow chart will be described to accompany the schematic view shown in FIG. 2. Some of the described stages can be replaced or eliminated in different embodiments. Additional features can be added to the semiconductor device structure. Some of the features described below can be replaced or eliminated in different embodiments.

The method S10 includes operation S11, in which the semiconductor wafer 50 is placed in a chamber 11 of a processing system 1. The processing system 1 includes a processing tool 10 with the chamber 11 defining an interior 110 where semiconductor manufacturing processes are conducted. The chamber 11 comprises an upper wall 111, a lower wall 112, and an outlet conduit 113 connected to the lower wall 112 for exhaust purposes.

The semiconductor wafer 50 in the chamber 11 is supported by a wafer stage 12 positioned within the interior 110 and mounted on the lower wall 112. The wafer stage 12 is a wafer chuck designed to hold the wafer securely during processing. The wafer chuck may employ electrostatic forces, vacuum suction, or mechanical clamping to maintain the wafer's position. In the embodiments of electrostatic chuck, electric fields are used to generate attractive forces between the chuck and the wafer, minimizing wafer movement and providing precise alignment during exposure. In the embodiments of vacuum chucks use negative pressure to secure the wafer, while mechanical clamps physically hold the wafer in place.

A shower head 13 is positioned on the upper wall 111 of the chamber 11 and distributes cleaning plasma, such as hydrogen plasma, into the interior 110. The shower head 13 includes multiple discharging holes arranged in a specific pattern to distribute the hydrogen plasma uniformly over the semiconductor wafer 50. The shower head 13 is constructed from materials such as aluminum or ceramic to withstand the reactive plasma environment. The shower head 13 may be formed with a diameter of approximately 100 to 150mm, a width of about 2032mm. The hole sizes of the discharging holes of the shower head 13 ranging from 0.8 to 1.2mm in diameter, and a total of 655 to 7350 holes to achieve the desired flow characteristics.

In some embodiments, the processing tool 10 functions as a lithography tool, exposing the semiconductor wafer 50 to radiation energy 140 generated by a radiation source 14. The radiation energy 140, for example, is Extreme Ultraviolet (EUV) light. EUV lithography is a technology that uses EUV light with a wavelength of approximately 13.5nm to achieve fine patterning on semiconductor wafers. The shorter wavelength allows for the resolution of smaller features. EUV lithography systems is performed in a vacuum environment to prevent the absorption of EUV light by air molecules, and optics, such as reflective mirrors coated with multilayer materials like molybdenum and silicon, direct and focus the EUV light onto the wafer.

To process the semiconductor wafer 50, a photoresist layer is coated onto the wafer surface before loading it onto the wafer stage 12. The photoresist is exposed to the radiation energy 140 during the lithography process. In the case of a positive photoresist, the exposed areas become more soluble in the developer solution, allowing those areas to be removed during development. In case of a negative photoresist, the exposed areas become less soluble, causing the unexposed regions to be washed away during development. This selective solubility change enables the transfer of the desired pattern onto the wafer, for defining circuit elements and interconnects in semiconductor devices.

The method S10 further includes operation S12, wherein one or more sensor, such as first sensor 31 and second sensor 32, are used to detect parameters within the chamber 11 during the processing of the semiconductor wafer 50. In some embodiments, the first sensor 31 and the second sensor 32are positioned at two different locations on the wafer stage 12, such as opposite sides near the peripheral edge 121 of the wafer stage 12. When the semiconductor wafer 50 is placed on the wafer stage 12, the first sensor 31 and the second sensor 32 are positioned between the peripheral edge 121 of the wafer stage 12 and the edge of the semiconductor wafer 50. The number of sensors 31, 32 would vary according to demands. In some embodiments, the second sensor 32 is omitted.

The first sensor 31 and the second sensor 32 may be used to detect optical parameters related to the lithography process. Possible types of sensors used in a lithography chamber include photodiodes, charge-coupled devices (CCDs), complementary metal-oxide-semiconductor (CMOS) sensors, and pyroelectric detectors. These sensors detect various aspects of the optical energy, such as intensity, wavelength, and uniformity of the radiation source. The detection signals produced by the first sensor 31 and the second sensor 32 may be used to adjust the processing parameters of the processing tool 10 in real time. The mechanism for real-time parameter adjustment involves feedback control systems that interpret sensor data and modify process variables accordingly. For instance, if the sensors detect a deviation in the intensity or uniformity of the radiation energy 140, the system adjusts the exposure dose, focus settings, or alignments to compensate for these variations. This allows the patterns to be accurately transferred onto the wafer, reducing defects and improving yield.

In some embodiments, hydrocarbons present within the chamber 11 can adsorb onto the surfaces of optical components, such as the multilayer mirrors and sensors. The hydrocarbons may adhere through physical interactions. Under exposure to the radiation energy 140, these hydrocarbons can crack and decompose, forming free carbon groups. These carbon groups polymerize chemically and become adsorbed on surfaces, leading to carbon contamination. Carbon contamination can adversely affect the performance of the first sensor 31 and the second sensor 32 by obscuring their optical surfaces and altering their detection capabilities. To mitigate this, a sensor cleaning process is performed, which includes operations S13 and S14.

In operation S13, cleaning plasma F1 is generated using a remote plasma module 20 positioned outside the chamber 11. The remote plasma module 20 comprises a gas source 21, a regulating member 22, a reaction region 23 and a power supply 24. The gas source 21 stores gas for creating plasma. In this embodiment, hydrogen gas is used. The regulating member 22 controls the flow rate of gas from the gas source 21 to the reaction region 23, where the hydrogen plasma is generated. The power supply 24 provides energy to create the plasma in the reaction region 23. The power supply 24 provides radio frequency (RF) or microwave (MW) energy ranging from about 30 watts to about 60 watts to ionize the gas within the reaction region 23, forming cleaning plasma, such as cleaning plasma F1.

By placing the remote plasma module 20 outside of the chamber 11, the maintenance and servicing of the remote plasma module 20 can be conducted without disrupting the main processing chamber. Components such as the gas source 21, regulating member 22, and power supply 24 are accessible for inspection and replacement during the semiconductor manufacturing process performed in the chamber 11.

It would be appreciate that while hydrogen is employed in this embodiment, other gases are utilized to clean contamination in plasma form. Alternative gases include oxygen, ammonia, nitrogen trifluoride (NF₃), and carbon tetrafluoride (CF₄). Oxygen plasma effectively removes organic contaminants through oxidation, while ammonia plasma cleans surfaces by forming volatile compounds with contaminants. NF₃ and CF₄ are used for cleaning purposes due to their ability to etch and remove deposited films. The choice of gas depends on the nature of the contamination and the materials involved in the chamber components.

In operation S14, the cleaning plasma F1 is discharged from the shower head 13 toward both the first sensor 31 and the second sensor 32 to remove contaminations formed on them.

Specifically, the cleaning plasma F1 is supplied into the shower head 13 via a supply line 25 at a flow rate of approximately 450 to 600 standard cubic centimeters per minute (sccm). When entering the shower head 13, a tunable bias voltage ranging from about -50 volts to about 50 volts is applied to further filter out hydrogen ions (H⁺) and electrons, producing filtered cleaning plasma F2. The advantage of using filtered cleaning plasma includes that it reduces the presence of charged particles that could damage sensitive optical components or sensors. By filtering out H⁺ ions and electrons, the neutral hydrogen radicals in filtered cleaning plasma F2 react with carbon contamination without causing plasma-induced damage or erosion to the sensor surfaces. This selective cleaning may keep the longevity and reliability of the sensors.

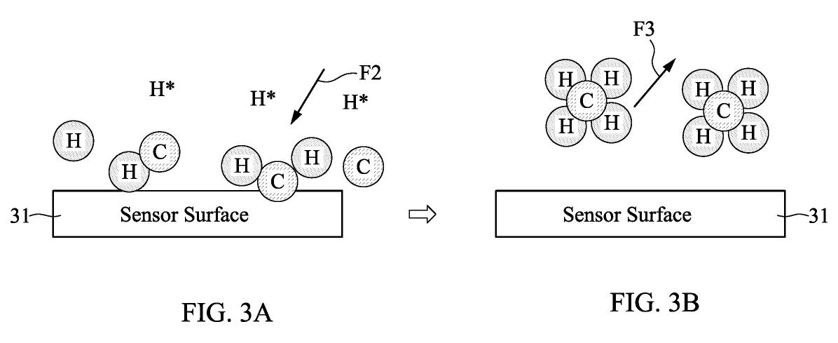

When the filtered cleaning plasma F2 is discharged into the interior 110 of the chamber 11, it addresses carbon contamination over a large area while simultaneously treating the first sensor 31 and the second sensor 32 within the chamber 11. The hydrogen plasma F2 reacts with the carbon contamination 35 (shown in FIG. 3A), converting it into methane (CH₄) or other hydrocarbon species through reactions such as C + H* → CₓH_y. The volatile byproducts are then removed from the chamber via an exhausting flow F3 (Shown in FIG. 3B) created by pump and exhausted via the outlet conduit 113 connected to the lower wall 112. This exhaust flow F3 aids in cleaning hydrocarbons from the chamber 11 and optical components.

In some embodiments, additional processes are incorporated to enhance the cleaning efficiency. For example, ultraviolet (UV) radiation is employed in conjunction with the plasma cleaning to break down stubborn contaminants. UV radiation can photodecompose certain organic compounds, making them more susceptible to reaction with the plasma species. In some embodiments, different configurations of the shower head 13 are utilized to tailor the distribution of the cleaning plasma. For instance, the arrangement and size of the discharging holes are modified to focus the plasma flow towards specific areas, such as the locations of the first sensor 31 and the second sensor 32. In some embodiments, movable or adjustable shower heads are employed to direct the plasma precisely where it is needed. In some embodiments, the wafer stage 12 is rotated around the rotation axis C1 while the discharging of the cleaning plasma from the shower head 13 such that the first sensor 31 and the second sensor 32 may be positioned in different locations in the chamber 11.

In some embodiments, the detection and cleaning processes are integrated into a closed-loop control system. The control system continuously monitors the output from the first sensor 31 and the second sensor 32 and determines the timing for initiating cleaning process. For example, if a preset threshold of contamination is detected based on the degradation of sensor signals, the system automatically triggers the plasma cleaning operation without manual intervention. This autonomous operation enhances the overall efficiency of the manufacturing process by reducing downtime and minimizing the risk of human error.

In some embodiments, the cleaning process parameters are adjusted based on the real time conditions within the chamber. Parameters such as plasma density, gas flow rates, and bias voltages are adjusted in response to environmental factors like temperature, pressure, and contamination levels. Adaptive control algorithms are implemented to fine-tune these parameters, enhancing the effectiveness of the cleaning process while protecting the chamber components.

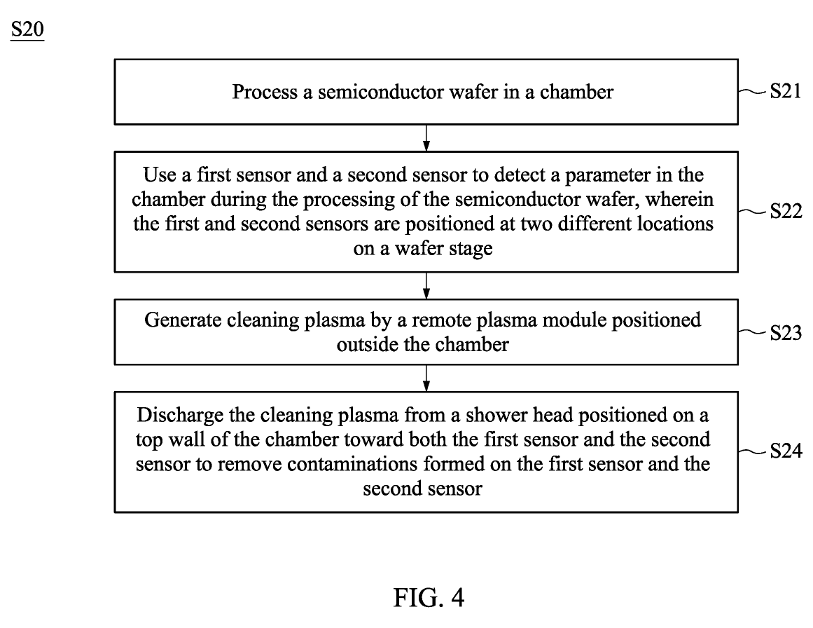

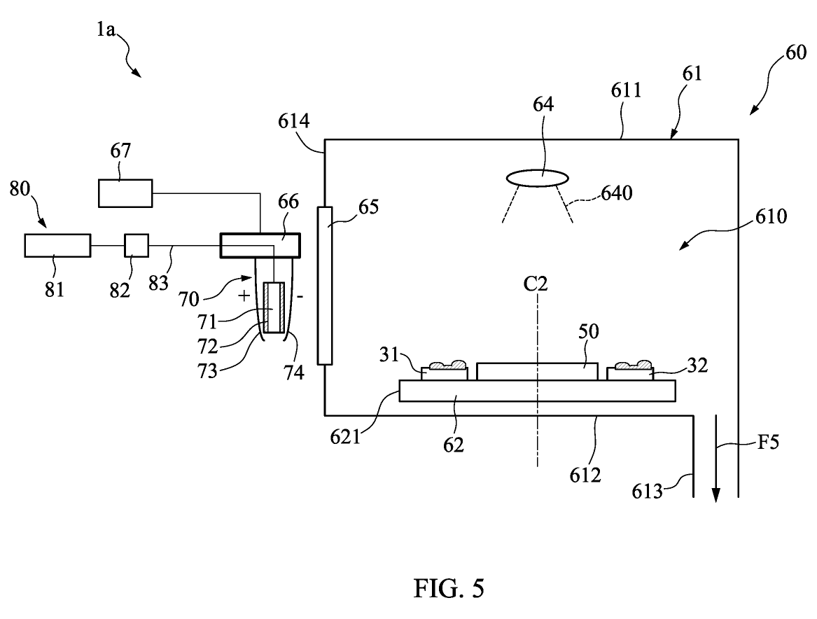

FIG. 4 is a flowchart of an alternative method S20 for manufacturing a semiconductor wafer, in accordance with other embodiments of the present disclosure. For illustration, the flow chart will be described to accompany the schematic view shown in FIGS. 5-9. Some of the described stages can be replaced or eliminated in different embodiments. Additional features can be added to the semiconductor device structure. Some of the features described below can be replaced or eliminated in different embodiments.

The method S20 includes operation S21, the semiconductor wafer 50 is placed in a chamber 61 of a processing system 1a. The processing system 1a includes a processing tool 60 with the chamber 61 defining an interior 610 where semiconductor manufacturing processes are performed. The chamber 61 comprises an upper wall 611, a lower wall 612, an outlet conduit 613 connected to the lower wall 612 for exhaust purposes, and a side wall 614 connected between the upper wall 611 and the lower wall 612. A door 65 is formed in the side wall 614 to facilitate access to the interior 610. The chamber 61 provides a controlled environment for precise semiconductor processing, including lithography process.

The semiconductor wafer 50 is supported by a wafer stage 62 positioned within the interior 610 and mounted on the lower wall 612. The wafer stage 62 is a wafer chuck designed to hold the wafer securely during processing. The wafer chuck may employ electrostatic forces, vacuum suction, or mechanical clamping to maintain the wafer's position. In some embodiments, the processing tool 60 functions as a lithography tool, exposing the semiconductor wafer 50 to radiation energy 640 generated by a radiation source 64. The radiation energy 640 is, for example, Extreme Ultraviolet (EUV) light.

The method S20 further includes operation S22, wherein sensors, such as the first sensor 31 and the second sensor 32, are used to detect parameters within the chamber 61 during the processing of the semiconductor wafer 50. The first and second sensors are positioned at two different locations on the wafer stage 62, such as opposite sides near the peripheral edge 621 of the wafer stage 62. When the semiconductor wafer 50 is placed on the wafer stage 62, the first sensor 31 and the second sensor 32 are positioned between the peripheral edge 621 of the wafer stage and the edge of the semiconductor wafer 50. These sensors 31, 32 detect optical parameters related to the lithography process, including intensity, uniformity, and wavelength of the radiation energy 640. The number of sensors 31, 32 would vary according to demands. In some embodiments, the second sensor 32 is omitted.

In some embodiments, hydrocarbons present within the chamber 61 can adsorb onto the surfaces of optical components, such as multilayer mirrors and sensors. Initially, the hydrocarbons adhere through physical interactions like van der Waals forces. Under exposure to the radiation energy 640, these hydrocarbons can crack and decompose, forming free carbon groups. These carbon groups polymerize chemically and become adsorbed on surfaces, leading to carbon contamination 35. Carbon contamination can adversely affect the performance of the first sensor 31 and the second sensor 32 by obscuring their optical surfaces and altering their detection capabilities. The accumulation of carbon layers can reduce sensor sensitivity, cause signal drift, and affect the accuracy of measurements. To mitigate this, a sensor cleaning process is performed, which includes operations S23 and S24.

In operation S23, hydrogen plasma is generated by a probe 70 positioned in the chamber 61. The probe 70 includes a passage 71 formed by a tube made from materials such as quartz. The tube is surrounded by a shell 72, which may be made of polylactic acid (PLA). Quartz can withstand high temperatures and is transparent to a wide range of wavelengths, making it suitable for applications involving plasma and high-energy radiation. The shell 72 made of PLA offers advantages in terms of insulation and structural support. PLA has good mechanical properties and provides adequate electrical insulation, which is useful for preventing electrical interference during plasma generation.

A gas supply module 80 is connected to the probe 70 for supplying gas to produce the cleaning plasma. The gas supply module 80 includes a gas source 81, a regulating member 82, and a supply line 83. The gas source 81 stores gas for creating plasma, such as hydrogen gas in this embodiment. The regulating member 82 controls the flow rate of gas from the gas source 81, so as to deliver appropriate amount of gas to the probe 70 for plasma generation. The supply line 83 connects the regulating member 82 to the passage 71 of the probe 70.

The probe 70 further includes electrodes 73 and 74 to excite the gas F4 supplied from the gas supply module 80. In some embodiments, the electrodes 73 and 74 are positioned at a lower end of the passage 71 adjacent to an outlet of the passage 71 to excite the gas once or before it leaves the passage 71. Alternatively, the electrodes can be arranged in different configurations to optimize plasma generation. For example, the electrodes may be placed along the length of the passage 71 or wrapped around the tube in a helical fashion. This arrangement can enhance the efficiency of plasma generation by providing a more uniform electric field and better ionization of the gas.

The electrodes 73 and 74 are connected to the power supply 67. The power supply 67 provides radio frequency (RF) power ranging from about 30 watts to about 60 watts to ionize the gas passing through the passage 71, forming the cleaning plasma F5. RF power is commonly used in plasma applications due to its ability to generate plasma at lower pressures and temperatures, which is beneficial for delicate components like sensors.

The probe 70 is mounted on a transferring member 66, such as a six-axis (6-axis) robotic arm. The transferring member 66 changes the angle or position of the probe 70. The 6-axis arm includes multiple joints and actuators that allow movement in three-dimensional space with high precision. The axes of movement include vertical, horizontal, and depth axes, as well as rotational movements around each of these axes. This enables the arm to position the probe 70 at precise locations and orientations within the chamber 61, without interfering with other components.

In operation S24, the cleaning plasma F5 is discharged from the probe 70 toward the first sensor 31 to remove contaminations formed on the sensor. In some embodiments, during the wafer processing operation, the probe 70 is in an idle position (as shown in FIG. 5) outside the chamber 61. By placing the probe 70 outside of the chamber, maintenance and servicing can be conducted without disrupting the main processing chamber. Components such as the tube of the probe 70 and transferring member 66 are accessible for inspection and replacement during semiconductor manufacturing processes.

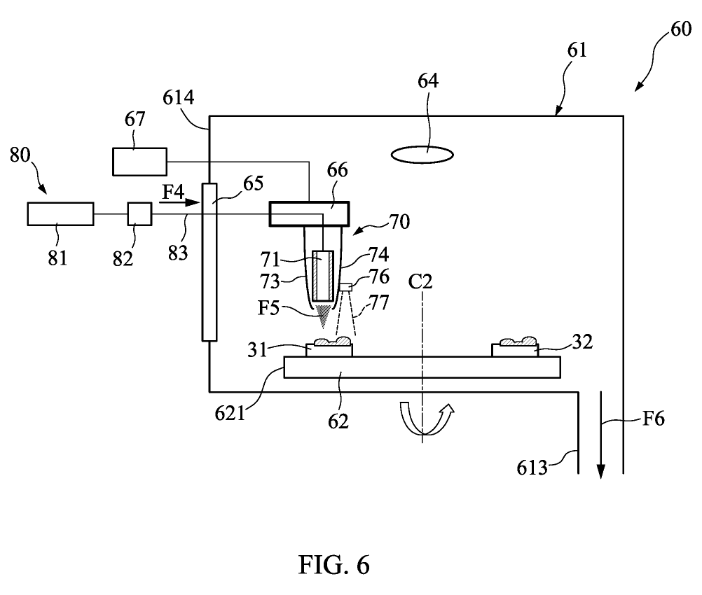

When the processing of the semiconductor wafer 50 is completed, the probe 70 is moved from the idle position to a first cleaning position (as shown in FIG. 6) through the door 65. When the probe 70 is within the chamber 61, the outlet of the probe is aligned with one of the sensors, such as the first sensor 31. Once the probe 70 is properly positioned, the gas F4, such as hydrogen gas, is supplied to the passage 71 of the probe and then excited by electric power applied by the electrodes 73 and 74 to generate the cleaning plasma F5.

When the cleaning plasma F5 is discharged into the interior 610 of the chamber 61, it addresses carbon contamination over the first sensor 31. The hydrogen plasma reacts with the carbon contamination 35, converting it into methane (CH₄) or other hydrocarbon species through reactions such as C + H* → CₓH_y. The hydrogen radicals in the plasma break down the carbon bonds, forming volatile compounds. The volatile byproducts are then removed from the chamber via an exhausting flow F6 created in the outlet conduit 613 connected to the lower wall 612.

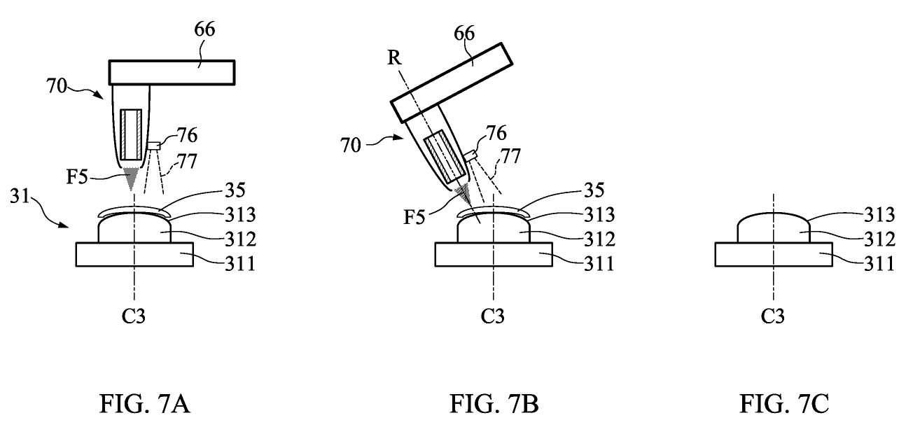

FIGS. 7A-7C are schematic views showing detailed stages of operation S24. In some embodiments, the first sensor 31 includes a base 311 for supporting purposes and housing electronic components such as a printed circuit board (PCB) and detection elements like diodes. For example, a photodiode can be used, which converts incident light into an electrical current proportional to the light intensity. An optical member 312 is positioned on the base 311 with a light transmission surface 313 for light passing therethrough. The light transmission surface 313 may be made of materials like fused silica or sapphire, which have high transparency and durability.

During the supply of cleaning plasma F5, the probe 70 is positioned aligned with the central axis C3 of the first sensor 31 and supplies the cleaning plasma F5 for a preset time period, such as 10 minutes to one hour. The duration depends on factors like the level of contamination and the effectiveness of the plasma cleaning process.

In some embodiments, a monitoring member 76 is employed during the supply of the cleaning plasma to determine whether the cleaning process is completed. The monitoring member 76 may be positioned next to the probe 70 and moved together with the probe 70 by the transferring member 66. In one exemplary embodiment, the monitoring member 76 outputs an optical signal 77 toward the first sensor 31 and detects changes in optical path length due to contamination layers. By measuring the intensity or phase shift of the reflected or transmitted signal, the monitoring member 76 can assess the level of contamination. If the optical path meets predefined standards, the cleaning process is terminated, otherwise, the cleaning process continues.

Alternatively, the monitoring member 76 may be a spectroscopic sensor that analyzes the spectral composition of reflected or transmitted light, providing detailed information about contaminants and their compositions. The data produced by the monitoring member 76 is transmitted to a control system (not shown) for analysis. The control system processes the data and adjusts the supply of cleaning plasma in real time according to the detected data. For example, in a closed-loop feedback control system, the control unit receives sensor data indicating the level of contamination and adjusts parameters such as plasma intensity, gas flow rate, or exposure duration to optimize the cleaning process. As a result, the cleaning process is performed effectively without over-processing, which could damage the sensor surface.

In some embodiments, the outlet of the probe 70 has a width that is smaller than the light transmission surface 313 of the first sensor 31. To clean the entire area of the light transmission surface 313, operation S24 includes moving the position of the probe 70 from the center of the first sensor 31 to the peripheral edge back and forth using the transferring member 66. This translational movement allows the plasma to reach all areas of the sensor surface, ensuring uniform cleaning.

In other embodiments, the light transmission surface 313 of the first sensor 31 is curved. In order to discharge hydrogen plasma toward the first sensor 31 at different angles, the angle of the probe 70 relative to the top surface of the first sensor is changed. For example, the angle of the probe 70 is adjusted during the supply of cleaning plasma F5 according to the curvature of the light transmission surface 313 of the first sensor 31, as shown in FIG. 7B. This adjustment changes the inclination angle of the longitudinal axis R of the probe 70 relative to the central axis C3 of the first sensor 31. The translational movement and angle adjustment may be performed simultaneously to ensure effective cleaning across the curved surface.

After the cleaning process is performed for a preset time period, the contamination is removed from the light transmission surface 313, as shown in FIG. 7C. The sensor's performance is restored, allowing accurate detection and monitoring during subsequent processing operations.

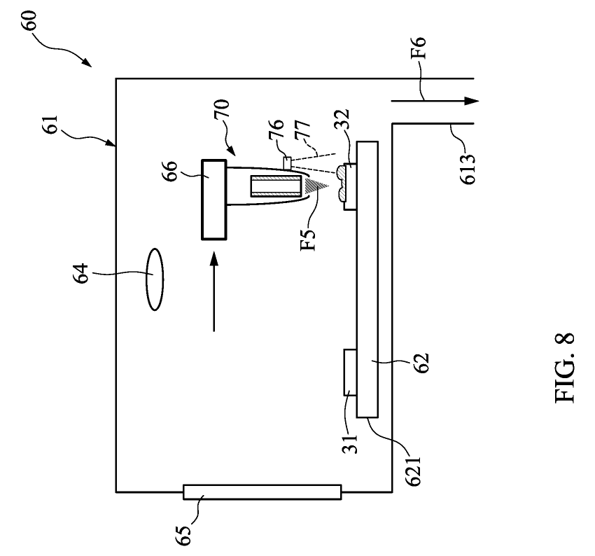

In cases where there are multiple sensors positioned in the chamber 61, the probe 70 is moved by the transferring member 66 from a first cleaning position to a second cleaning position above the second sensor 32, as shown in FIG. 8. The probe 70 is translationally moved from the first sensor 31 to the second sensor 32 after the completion of the cleaning of the first sensor 31. To clean the second sensor 32, a similar process described for the first sensor 31 is applied.

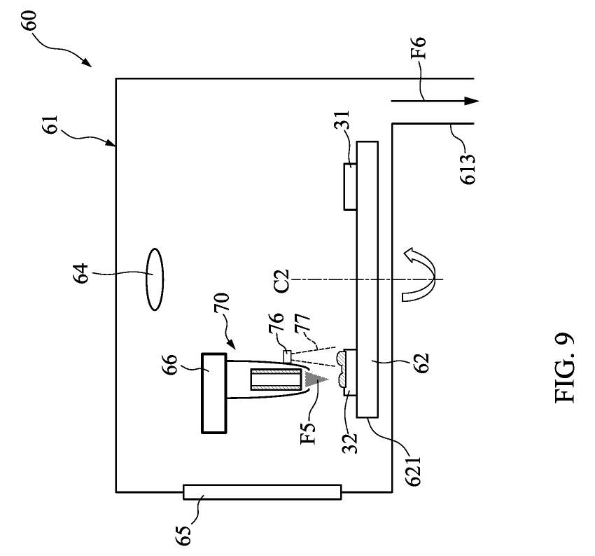

Alternatively, after the completion of the cleaning of the first sensor 31, the position of the probe 70 is unchanged or slightly moved. As shown in FIG. 9, the wafer stage 62, on which the first sensor 31 and the second sensor 32 are positioned, is rotated or moved to change the positions of the sensors, thereby moving the second sensor 32 beneath the probe 70. This method enable the probe 70 to clean different sensors in the chamber 61 without extensive movement, which helps prevent collision with other components during transferring the probe 70 within the chamber.

In some embodiments, the methods S10 and S20 described are applicable beyond EUV lithography and can be adapted for use in other semiconductor processing equipment. For instance, in plasma etching or chemical vapor deposition (CVD) systems, similar contamination issues arise due to the deposition of unwanted materials on sensors and chamber components. The described cleaning techniques are adapted accordingly to address contaminations in different processing environments.

Embodiments of the present disclosure describe a method and system for manufacturing semiconductor wafers that incorporate in-situ cleaning of sensors using cleaning plasma generated by a probe within the chamber or by a remote plasma module. Addressing contamination and enabling real-time parameter adjustments enhances the efficiency and reliability of semiconductor processing systems.

Compared with conventional methods, such as passing hydrogen gas over a hot filament (temperature approximately 2000°C), where the heated gas is injected directly onto the sensor surface, the disclosed method offers several advantages. High-temperature processes may cause thermal effects, requiring more time (over two hours) for the temperature to stabilize. Such practices can affect overlay performance due to thermal expansion and contraction, necessitating additional time to wait for the sensor and chamber to cool down. This impacts production throughput and can lead to increased downtime. Conversely, the embodiments of this disclosure use cleaning plasma at relatively low temperature to remove carbon contamination, replacing the high-temperature process. For example, the remote plasma and plasma probe use hydrogen plasma generated with an RF power source, where the temperature is lower than 300°C. This lower temperature approach reduces thermal stress on the sensors and reduce extra time to wait for sensors to cool down, thereby increasing wafer production throughput. Since the sensor is not cleaned with hot fluids, the lifetime of the sensor is extended without adverse thermal effects

According to one embodiment of the present disclosure, a sensor cleaning method is provided. The method includes processing a semiconductor wafer in a chamber. The method further includes using a first sensor to detect a parameter in the chamber during the processing of the semiconductor wafer. The method also includes generating cleaning plasma by a probe positioned in the chamber, wherein a gas is supplied to a passage in the probe and is excited into cleaning plasma by electric power supplied by electrodes positioned next to the passage. In addition, the method includes discharging the cleaning plasma from the probe toward the first sensor to remove contaminations formed on the first sensor.

According to another embodiment of the present disclosure, a sensor cleaning method is provided. The method includes processing a semiconductor wafer in a chamber. The method further includes using a first sensor and a second sensor to detect a parameter in the chamber during the processing of the semiconductor wafer. The first and second sensors are positioned at two different locations on a wafer stage. The method also includes generating cleaning plasma by a remote plasma module positioned outside the chamber. In addition, the method includes discharging the cleaning plasma from a shower head positioned on a top wall of the chamber toward both the first sensor and the second sensor to remove contaminations formed on the first sensor and the second sensor.

According to yet another embodiment of the present disclosure a semiconductor manufacturing system is provided. The system includes a chamber, a wafer stage, a radiation source, and a first sensor. The wafer stage is used to support a semiconductor wafer. The radiation source is used to project energy over the semiconductor wafer for performing a processing. The first sensor is positioned in the chamber to detect the energy from the radiation source during the process. The system further includes a probe including a passage and electrodes positioned adjacent to the passage. The system also includes a gas source connected to the probe and configured to supply gas to the passage of the probe. In addition, the system includes a power supply electrically connected to the electrodes of the probe. When the process is performed, the probe is in an idle position, and when the process is completed, the probe is moved from the idle position to a first cleaning position above the first sensor, in the first cleaning position, the gas is supplied to the passage of the probe and then excited by electric power applied by the electrodes to generate cleaning plasma to clean the first sensor.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
processing a semiconductor wafer in a chamber;
using a first sensor to detect a parameter in the chamber during the processing of the semiconductor wafer;
generating cleaning plasma by a probe positioned in the chamber, wherein a gas is supplied to a passage in the probe and is excited into cleaning plasma by electric power supplied by electrodes positioned next to the passage; and
discharging the cleaning plasma from the probe toward the first sensor to remove contaminations formed on the first sensor.

2. The method of claim 1, wherein the cleaning plasma include hydrogen plasma.

3. The method of claim 1, further comprising changing an angle of the probe relative to a surface of the first sensor to discharge cleaning plasma toward the first sensor at different angles.

4. The method of claim 1, further comprising moving the position of the probe from a center of the sensor to a peripheral edge of the sensor.

5. The method of claim 1, wherein the cleaning plasma is generated by the electrodes provided at a lower end of the passage.

6. The method of claim 1, further comprising:
using a second sensor to detect the parameter in the chamber; and
discharging the cleaning plasma from the probe toward the second sensor to remove contaminations formed on the second sensor after the cleaning of the first sensor is completed.

7. The method of claim 6, further comprising translationally moving the probe from the first sensor to the second sensor after the completion of the cleaning of the first sensor.

8. The method of claim 6, further comprising, after the completion of the cleaning of the first sensor, rotating a wafer stage on which the first sensor and the second sensor are positioned, so as to change the positions of the first sensor and the second sensor, thereby moving the second sensor below the probe.

9. The method of claim 1, further comprising detecting, by a monitoring member, a condition of the contaminations formed on the first sensor, to determine whether the cleaning process is completed.

10. The method of claim 1, wherein the cleaning of the first sensor is performed after the completion of the processing of a semiconductor wafer, and once the cleaning of the first sensor is completed, the processing of another semiconductor wafer in the chamber is performed.

11. The method of claim 1, wherein the contamination on the first sensor includes carbon contamination.

12. The method of claim 1, wherein an EUV lithography process is performed over the semiconductor wafer in the chamber.

13. A method comprising:
processing a semiconductor wafer in a chamber;
using a first sensor and a second sensor to detect a parameter in the chamber during the processing of the semiconductor wafer, wherein the first and second sensors are positioned at two different locations on a wafer stage;
generating cleaning plasma by a remote plasma module positioned outside the chamber; and
discharging the cleaning plasma from a shower head positioned on an upper wall of the chamber toward both the first sensor and the second sensor to remove contaminations formed on the first sensor and the second sensor.

14. The method of claim 13, further comprising applying a bias electric power to the shower head to filter out ions and electrons approaching the first sensor and second sensor.

15. The method of claim 13, further comprising evacuating gas from the chamber while discharging the cleaning plasma.

16. A system comprising:
a chamber;
a wafer stage configured to support a semiconductor wafer;
a radiation source configured to project energy over the semiconductor wafer for performing a process;
a first sensor positioned in the chamber to detect the energy from the radiation source during the process;
a probe comprising a passage and electrodes positioned adjacent to the passage;
a gas source connected to the probe and configured to supply gas to the passage of the probe; and
a power supply electrically connected to the electrodes of the probe,
wherein when the process is performed, the probe is in an idle position, and when the process is completed, the probe is moved from the idle position to a first cleaning position above the first sensor, in the first cleaning position, the gas is supplied to the passage of the probe and then excited by electric power applied by the electrodes to generate cleaning plasma to clean the first sensor.

17. The system of claim 16, further comprising a second sensor positioned in the chamber, wherein the probe is movable from the first cleaning position to a second cleaning position above the second sensor.

18. The system of claim 17, wherein the first sensor and the second sensor are positioned at two different positions on the wafer stage, and the probe is translationally moved from the first cleaning position to the second cleaning position across the wafer stage.

19. The system of claim 16, wherein an outlet of the probe has a width that is smaller than a light transmission surface of the first sensor.

20. The system of claim 16, further comprising a transferring member connected to the probe to change an angle or a position of the probe relative to the transmission surface.
